(19) United States
(12) Patent Application Publication
(10) Pub. No.: US 2010/0000594 A1
(43) Pub. Date: Jan. 7, 2010

(54) SOLAR CONCENTRATORS WITH TEMPERATURE REGULATION

(75) Inventors: James Thomas Zalusky, Beavercreek, OH (US); Neil D. Sater, Brecksville, OH (US); Terry L. Zahuranec, North Olmsted, OH (US)

Correspondence Address: TUROCY & WATSON, LLP, 127 Public Square, 57th Floor, Key Tower, CLEVELAND, OH, 44114, US

(73) Assignee: GREENFIELD SOLAR CORP., North Ridgeville, OH (US)

(21) Appl. No.: 12/495,136

(22) Filed: Jun. 30, 2009

Related U.S. Application Data
(60) Provisional application No. 61/078,029, filed on Jul. 3, 2008.

(51) Int. Cl. H01L 31/052

(52) U.S. Cl. 136/246

(57) ABSTRACT

Systems and methods that regulate (e.g., in real time) heat dissipation from solar concentrators. A heat regulating assembly removes heat from the PV cells and other hot regions, to maintain the temperature gradient within predetermined levels. A control component can regulate (e.g., automatically) operation of valves (which the cooling medium flows through) based on sensor data (e.g., measurement of temperature, pressure, flow rate, velocity of the cooling medium, and the like throughout the system.)

### CROSS REFERENCE TO RELATED APPLICATIONS

This application claims the benefit of U.S. Provisional Application No. 61/078,029 filed on 3 Jul. 2008 entitled “SOLAR CONCENTRATORS WITH TEMPERATURE REGULATION” the entirety of this application is hereby incorporated by reference.

### BACKGROUND

Limited supply of fossil energy resources and their associated global environmental damage have compelled market forces to diversify energy resources and related technologies. One such resource that has received significant attention is solar energy, which employs photovoltaic technology to convert light into electricity. Typically, photovoltaic production has been doubling every two years, increasing by an average of 48 percent each year since year 2002, making it the world's fastest-growing energy technology. By midyear 2008, estimates for cumulative global solar energy production stands to at least 12,400 megawatts. Approximately 90% of such generating capacity consists of grid-tied electrical systems, wherein installations can be ground-mounted or built into roof or walls of a building, known as Building Integrated Photovoltaic (BIPV).

Moreover, significant technological progress has been achieved in design and production of solar panels, which are further accompanied by increased efficiency and reductions in manufacturing cost. In general, a major cost element involved in establishment of a wide-scale solar energy collection system is cost of support structure, which is employed to mount the solar panels of the array in proper position for receiving and converting solar energy. Other complexities in such arrangements involve efficient operations for the photovoltaic elements.

The photovoltaic elements for converting light to electric energy are commonly applied as solar cells to power supplies for small power in consumer-oriented products, such as desktop calculators, watches, and the like. Such systems are drawing attention as to their practical for future alternate power of fossil fuels. In general, photovoltaic elements are elements employing the photoelectromotive force (photovoltage) of the pn junction, the Schottky junction, or semiconductors, in which the semiconductor of silicon, or the like absorbs the light to generate photocarriers such as electrons and holes, and the photocarriers drift outside due to an internal electric field of the pn junction part.

One common photovoltaic element employs single-crystal silicon as a material, and semiconductor processes produce most of such photovoltaic elements. For example, a crystal growth process prepares a single crystal of silicon valency-controlled in the p-type or in the n-type, wherein such single crystal is subsequently sliced into silicon wafers to achieve desired thicknesses. Furthermore, the p-n junction can be prepared by forming layers of different conduction types, such as diffusion of a valance controller to make the conduction type opposite to that of a wafer.

Moreover, solar energy collection systems are employed for a variety of purposes, for example, as utility interactive power systems, power supplies for remote or unmanned sites, and cellular phone switch-site power supplies. An array of energy conversion modules, such as, photovoltaic (PV) modules, in a solar energy collection system can have a capacity from a few kilowatts to a hundred kilowatts or more, depending upon the number of PV modules, also known as solar panels, used to form the array. The solar panels can be installed wherever there is exposure to the sun for significant portions of the day.

Typically, a solar energy collection system includes an array of solar panels arranged in form of rows and mounted on a support structure. Such solar panels can be oriented to optimize the solar panel energy output to suit the particular solar energy collection system design requirements. Solar panels can be mounted on a fixed structure, with a fixed orientation and fixed tilt, or can be mounted on a tracking structure that aims the solar panels toward the sun as the sun moves across the sky during the day and as the sun path moves in the sky during the year.

Nonetheless, controlling temperature of the photovoltaic cells remains critical for operation of such systems, and associated scalability remains a challenging task. Common approximations conclude that typically about 0.3% power is lost for every 1° C. rise in the photovoltaic cell.

### SUMMARY

The following presents a simplified summary in order to provide a basic understanding of some aspects of the claimed subject matter. This summary is not an extensive overview. It is not intended to identify key/critical elements or to delineate the scope of the claimed subject matter. Its sole purpose is to present some concepts in a simplified form as a prelude to the more detailed description that is presented later.

The subject innovation supplies a system of solar concentrators with a heat regulating assembly, which regulates (e.g., in real time) heat dissipation therefrom. Such system of solar concentrators can include a modular arrangement of photovoltaic (PV) cells, wherein the heat regulating assembly can remove generated heat from hot spot areas to maintain temperature gradient for the modular arrangement of PV cells within predetermined levels. In one aspect, such heat regulating assembly can be in form of a heat sink arrangement, which includes a plurality of heat sinks to be surface mounted to a back side of the modular arrangement of photovoltaic cells, wherein each heat sink can further include a plurality of fins extending substantially perpendicular the back side. The fins can expand a surface area of the heat sink to increase contact with cooling medium (e.g., air, cooling fluid such as water), which is employed to dissipate heat from the fins and/or photovoltaic cells. As such, heat from the photovoltaic cells can be conducted through the heat sink and into surrounding cooling medium. Moreover, the heat sinks can have a substantially small form factor relative to the photovoltaic cell, to enable efficient distribution throughout the backside of the modular arrangement of photovoltaic cells. In one aspect, heat from the photovoltaic cells can be conducted through thermal conducting paths (e.g., metal layers), to the heat sinks to mitigate direct physical or thermal conduct of the heat sinks to the photovoltaic cells. Such an arrangement provides a scalable solution for proper operation of the PV modular arrangement.

In a related aspect, the heat sinks can be positioned in a variety of planar or three dimensional arrangements as to monitor, regulate and over all manage heat flow away from the photovoltaic cells. Moreover, each heat sink can further employ thermo/electrical structures that can have a shape of a spiral, twister, corkscrew, maze, or other structural shapes with a denser pattern distribution of lines in one portion and a relatively less dense pattern distribution of lines in other portions. For example, one portion of such structures can be formed of a material that provides relatively high isotropic conductivity and another portion can be formed of a material that provides high thermal conductivity in another direction. Accordingly, each thermo/electrical structure of the heat regulating assembly provides for a heat conducting path that can dissipate heat from the hot spots and into the various heat conducting layers, or associated heat sinks, of the heat regulating device.

Another aspect of the subject innovation provides for a heat regulating device with a base or back plate that can be kept in direct contact with a hot spot region of the modular photovoltaic arrangement. The base plate can include a heat promoting section and main base plate section. The heat promoting section facilitates heat transfer between the modular photovoltaic arrangement and the heat regulating device. The main base plate section can further include thermo structures embedded inside. Such permits for the heat generated from a photovoltaic cell to be initially diffused or dispersed through the whole main base plate section and then into the thermo structure spreading assembly, wherein such spreading assembly can be connected to the heat sinks.

According to a further aspect, the assembly of thermo structures can be connected to form a network with its operation controlled by a controller. In response to data gathered from the system (e.g., sensors, the thermo/electric structure assembly, and the like) the controller determines the amount and speed in which the cooling medium is to be released for interaction with the thermal structure (e.g., to take heat out of the photovoltaic cells so that the hot spots are eliminated and a more uniform temperature gradient is achieved in the modular arrangement of photovoltaic cells.) For example, based on collected measurements, a microprocessor regulates operation of a valve to maintain temperature within a predetermined range (e.g., water acting as a coolant supplied from a reservoir to flow through the PV cells.) Moreover, the system can incorporate various sensors to assess proper operation (e.g., health of the system) and to diagnose problems for rapid maintenance. In one aspect, upon exiting the heat regulating device and/or photovoltaic cells, the coolant can enter a Venturi tube, wherein pressure sensors enable a measurement of a flow rate thereof. Such further enables for verification of: the flow rate set, amount of coolant, blockages to the flow, and the like by a microprocessor of the control system.

In a related aspect, the system of solar concentrators can further include solar thermals—wherein the heat regulating assembly of the subject innovation can also be implemented as part of such hybrid system that produces both electrical energy and thermal energy, to facilitate optimizing energy output. Put differently, the thermal energy accumulated in the medium employed for cooling PV cells during a cooling process thereof, can subsequently serve as preheated medium or for thermal generation (e.g., supplied to customers—such as thermal loads.) The controller of the subject innovation can also actively manage (e.g., in real time) tradeoff between thermal energy and PV efficiency, wherein a control network of valves can regulate flow of coolant medium through each solar concentrator. The heat regulating assembly can be in form of a network of conduits, such as pipelines for channeling a cooling medium (e.g., pressurized and/or under free flow), throughout a grid of solar concentrators. The control component can regulate (e.g., automatically) operation of the valves based on sensor data (e.g., measurement of temperature, pressure, flow rate, fluid velocity, and the like throughout the system.)

To the accomplishment of the foregoing and related ends, certain illustrative aspects (not to scale) of the claimed subject matter are described herein in connection with the following description and the annexed drawings. These aspects are indicative of various ways in which the subject matter may be practiced, all of which are intended to be within the scope of the claimed subject matter. Other advantages and novel features may become apparent from the following detailed description when considered in conjunction with the drawings.

### BRIEF DESCRIPTION OF THE DRAWINGS

FIG. 1 illustrates a schematic block diagram of a cross sectional view for heat regulating device that dissipates heat from a modular arrangement of photovoltaic (PV) cells according to an aspect of the subject innovation.

FIG. 2 illustrates a schematic perspective for an assembly layout of the modular arrangement of PV cells in form of a PV grid in accordance with an aspect of the subject innovation.

FIG. 3 illustrates a schematic block diagram of a heat regulation system according to a further aspect of the subject innovation.

FIG. 4 illustrates an exemplary temperature grid pattern to monitor a PV grid assembly according to an aspect of the subject innovation.

FIG. 5 is a representative table of temperature amplitudes taken at the various grid blocks according to a further aspect of the subject innovation.

FIG. 6 illustrates a schematic diagram of a system that controls temperature of the photovoltaic grid assembly according to a particular aspect of the subject innovation.

FIG. 7 illustrates a related methodology of dissipating heat from PV cells according to an aspect of the subject innovation.

FIG. 8 illustrates a further methodology of heat dissipation for a PV grid assembly according to an aspect of the subject innovation.

FIG. 9 illustrates a schematic block diagram of a system that employs fluid as the cooling medium according to an aspect of the subject innovation.

FIG. 10 illustrates an exemplary solar grid arrangement that employs a heat regulating assembly according to a further aspect of the subject innovation.

FIG. 11 illustrates a related methodology for operation of the heat regulating assembly according to an aspect of the subject innovation.

FIG. 12 illustrates a further schematic block diagram of a sample-computing environment for the controllers of subject innovation.

### DETAILED DESCRIPTION

The various aspects of the subject innovation are now described with reference to the annexed drawings, wherein like numerals refer to like or corresponding elements throughout. It should be understood, however, that the drawings and detailed description relating thereto are not intended to limit the claimed subject matter to the particular form disclosed. Rather, the intention is to cover all modifications, equivalents, and alternatives falling within the spirit and scope of the claimed subject matter.

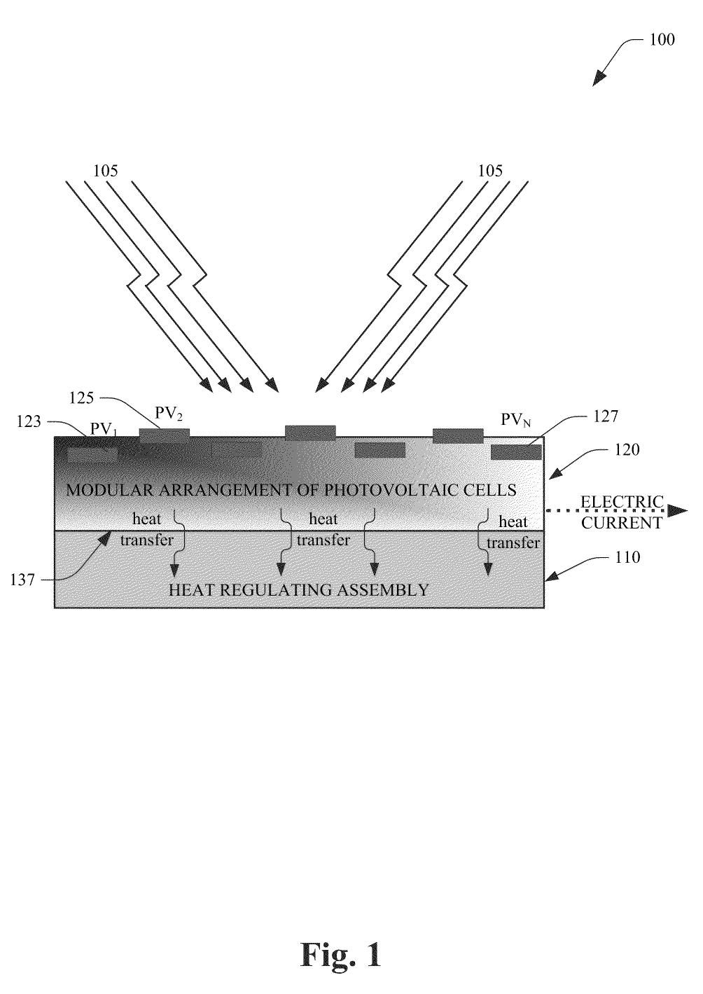

FIG. 1 illustrates a schematic cross sectional view 100 for a heat regulation assembly 110 that underlies a modular arrangement 120 of photovoltaic (PV) cells 123, 125, 127 (1 through N, where N is an integer), which has a variant temperature gradient. Typically, each of the PV cells (also referred to as solar cells) 123, 125, 127 can convert light (e.g., sunlight) into electrical energy. The modular arrangement 120 of the PV cells can include standardized units or segment that facilitate construction and provide for a flexible arrangement.

In one exemplary aspect, each of the photovoltaic cells 123, 125, 127 can be a dye-sensitized solar cell (DSC) that includes a plurality of glass substrates (not shown), wherein deposited thereon are transparent conducting coating, such as a layer of fluorine-doped tin oxide, for example.

Such DSC can further include a semiconductor layer such as TiO₂ particles, a sensitizing dye layer, an electrolyte and a catalyst layer such as Pt—(not shown)—which can be sandwiched between the glass substrates. A semiconductor layer can further be deposited on the coating of the glass substrate, and the dye layer can be sorbed on the semiconductor layer as a monolayer, for example. Hence, an electrode and a counter electrode can be formed with a redox mediator to control of electron flows therebetween.

Accordingly, the cells 123, 125, 127 experience cycles of excitation, oxidation, and reduction, which produce a flow of electrons, e.g., electrical energy. For example, incident light 105 excites dye molecules in the dye layer, wherein the photo excited dye molecules subsequently inject electrons into the conduction band of the semiconductor layer. Such can cause oxidation of the dye molecules, wherein the injected electrons can flow through the semiconductor layer to form an electrical current. Thereafter, the electrons reduce electrolyte at catalyst layer, and reverse the oxidized dye molecules to a neutral state. Such cycle of excitation, oxidation, and reduction can be continuously repeated to provide electrical energy.

The heat regulating device 110 removes generated heat from hot spot areas to maintain the temperature gradient for the modular arrangement 120 of PV within predetermined levels. The heat regulating device 110 can be in form of a heat sink assembly, which includes a plurality of heat sinks that can be surface mounted to a back side 137 of the modular arrangement of photovoltaic cells 120, wherein each heat sink can further include a plurality of fins (not shown) extending substantially perpendicular the back side. Such heat sinks can be fabricated from material with substantially high thermal conducting such as aluminum alloys, copper and the like. In addition, various clamping mechanisms or thermal adhesives and the like can be employed to securely hold the heat sinks without a level of pressure that can potentially crush the modular arrangement of photovoltaic cells 120. Moreover, “tube” style elements circulated with cooling fluid (e.g., water) therein can meander throughout the heat regulating device in a snake like formation, to further facilitate heat exchange.

The fins can expand a surface area of the heat sink to increase contact with cooling medium (e.g., air, cooling fluid such as water), which is employed to dissipate heat from the fins and/or photovoltaic cells. As such, heat from the photovoltaic cells can be conducted through the heat sink and into surrounding cooling medium. Moreover, the heat sinks can have a substantially small form factor relative to the photovoltaic cell, to enable efficient distribution throughout the backside 137 of the modular arrangement 120 of the photovoltaic cells.

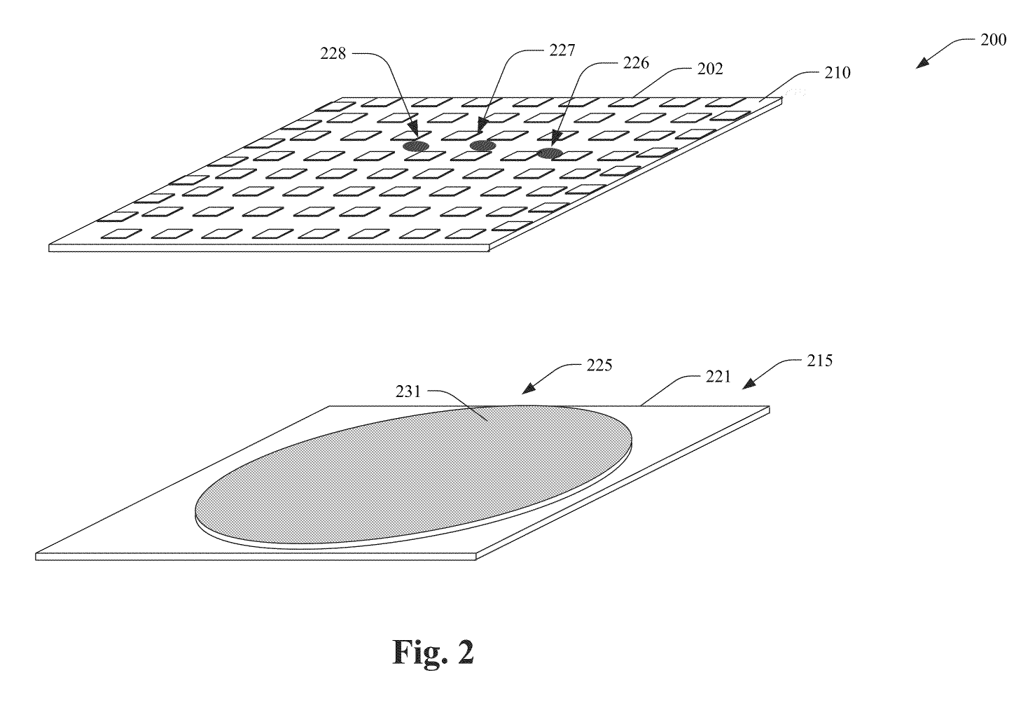

FIG. 2 illustrates a schematic perspective assembly layout 200 of a modular arrangement of PV cells in form of photovoltaic grid 210. Such grid 210 can be part of a single enclosure that converts solar energy into electrical energy. The heat regulating assembly can be arranged in form of a heat transfer layer 215 that includes heat sinks, which are thermally coupled to PV cells 202 on the PV grid 210. Even though the subject innovation is primarily described as the heat transfer layer 215 dissipating heat from the PV grid 210, it is to be appreciated that such heat transfer layer 215 can also be employed to selectively induce heat within segments of the PV grid 210 (e.g., to alleviate environmental factors, such as ice build up thereon.) The system 200 receives light reflected from reflecting plates such as mirrors (not shown).

In one aspect, the heat transfer layer 215 exists on a plane below the PV grid 210 and is thermally coupled thereto. The heat transfer layer 215 can include heat sinks that can be added to such layer via pick and place equipment that are commonly employed for placement of components and devices. In a related aspect, the heat transfer layer 215 can further include a base plate 221 that can be kept in direct contact with hot spots 226, 227, 228 that are generated on the PV grid 210.

In addition, the heat transfer layer 215 can include a heat promoting section 225. The heat promoting section 225 facilitates heat transfer between the PV grid 210 and the heat transfer layer 215. The heat promoting section 225 can further include thermo/electrical structures embedded inside. Such permits for the heat generated from a photovoltaic cell 202 to be initially diffused or dispersed through the whole main base plate section 221 and then into the thermo structure spreading assembly, wherein such spreading assembly can be connected to the heat sinks. The thermo structures can further include thermal conducting paths (e.g., metal layers) 231, to the heat sinks to mitigate direct physical or thermal conduct of the heat sinks to the photovoltaic cells. Such an arrangement provides a scalable solution for proper operation of the PV modular arrangement 210.

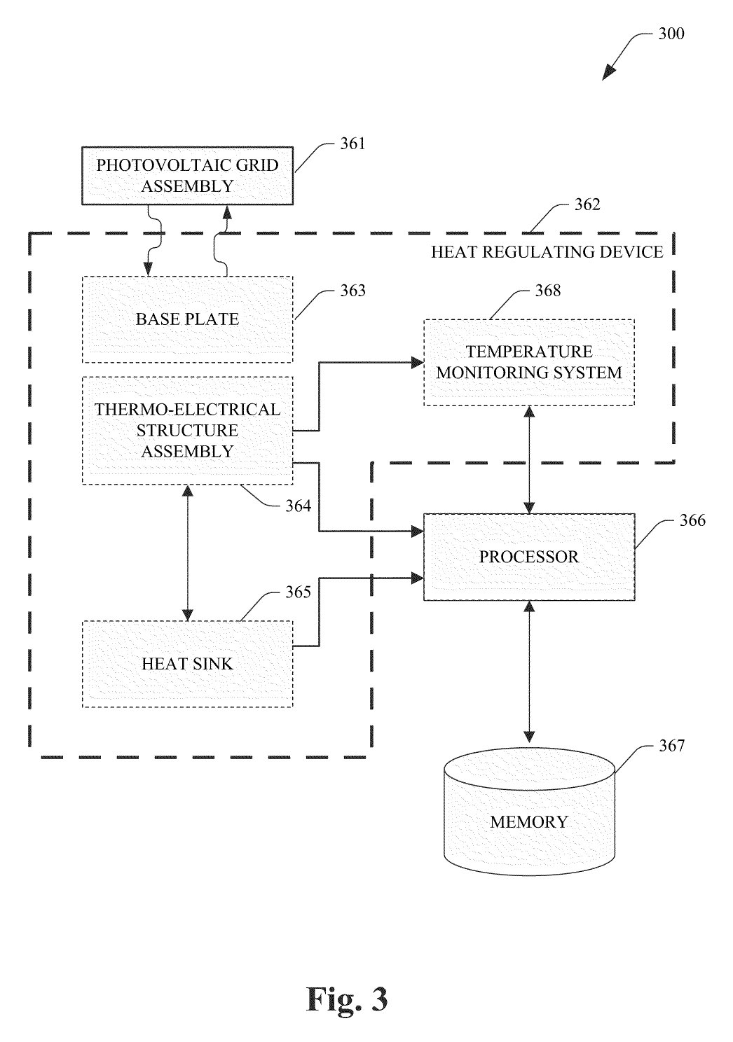

FIG. 3 illustrates a schematic block diagram of a heat regulation system 300 according to one aspect of the subject innovation. The system 300 includes a heat regulating device 362, which further comprises a thermo-electrical network assembly 364 operatively coupled to a back plate 363 that interacts with the photovoltaic grid assembly 361. The thermo-electrical net work assembly 364 can consist of a plurality of thermo-electric structures, (such as a trough formed within a layer of the heat regulating device, and embedded with various electronic components), and can be operatively coupled to the heat sink 365, which draws heat away from the thermo-electrical structure assembly 364. In addition, the thermo-electrical structure assembly 364 can be physically, thermally, or electrically connected to the back plate, which in turn contacts the photovoltaic grid assembly 361. Such an arrangement enables the photovoltaic grid assembly 361 to interact with thermo-electrical structure assembly 364 as a whole, via the back plate 363, as opposed to a portion of the photovoltaic grid assembly interacting with a respective individual thermo-electrical structure unit. A processor 366 can be operatively coupled to the thermo-electrical network assembly 364 and be programmed to control and operate the various components within the heat regulating device 362. Moreover, a temperature monitoring system 368 can be operatively connected to the processor 366 and the photovoltaic grid assembly 361, (via the back plate or base plate 363). The temperature monitoring system 368 operates to monitor temperature of the photovoltaic grid assembly 361. Temperature data are then provided to the processor 366, which employs such data in controlling the heat regulating device 362. The processor 366 can further be part of an intelligent device that has the ability to sense or display information, or convert analog information into digital, or perform mathematical manipulation of digital data, or interpret the result of mathematical manipulation, or make decisions based on the information. As such, the processor 366 can be part of a logic unit, a computer or any other intelligent device capable of making decisions based on the data gathered by the thermo-electrical structure and the information provided to it by the heat regulating device 362. A memory 367 being coupled to the processor 366 is also included in the system 300 and serves to store program code executed by the processor 366 for carrying out operating functions of the system 300 as described herein. The memory 367 can include read only memory (ROM) and random access memory (RAM). The ROM contains among other code the Basic Input-Output System (BIOS), which controls the basic hardware operations of the system 360. The RAM is the main memory into which the operating system and application programs are loaded. The memory 367 also serves as a storage medium for temporarily storing information such as PV cell temperature, temperature tables, allowable temperature, properties of the thermo-electrical structure, and other data employed in carrying out the present invention. For mass data storage, the memory 367 can include a hard disk drive (e.g., 10 Gigabyte hard drive).

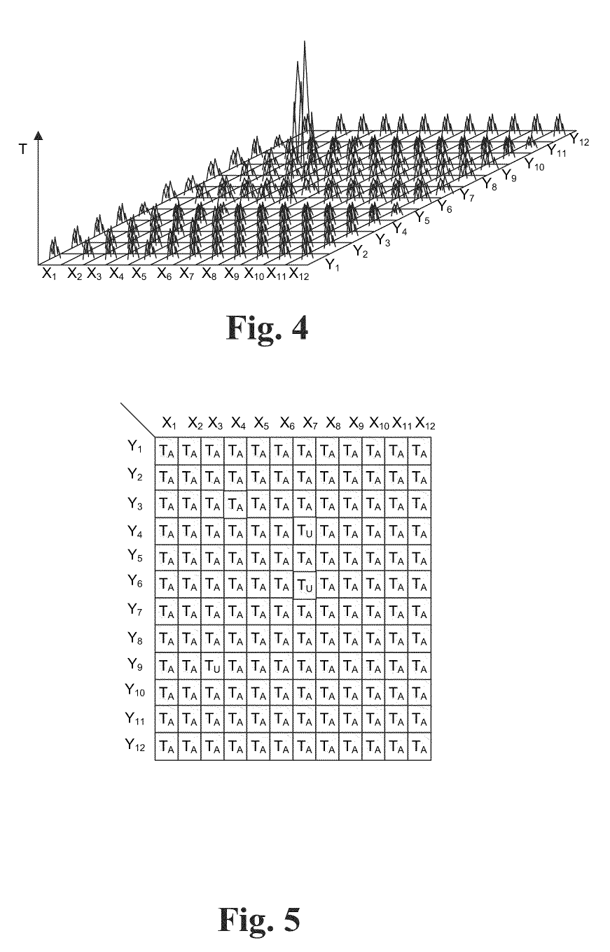

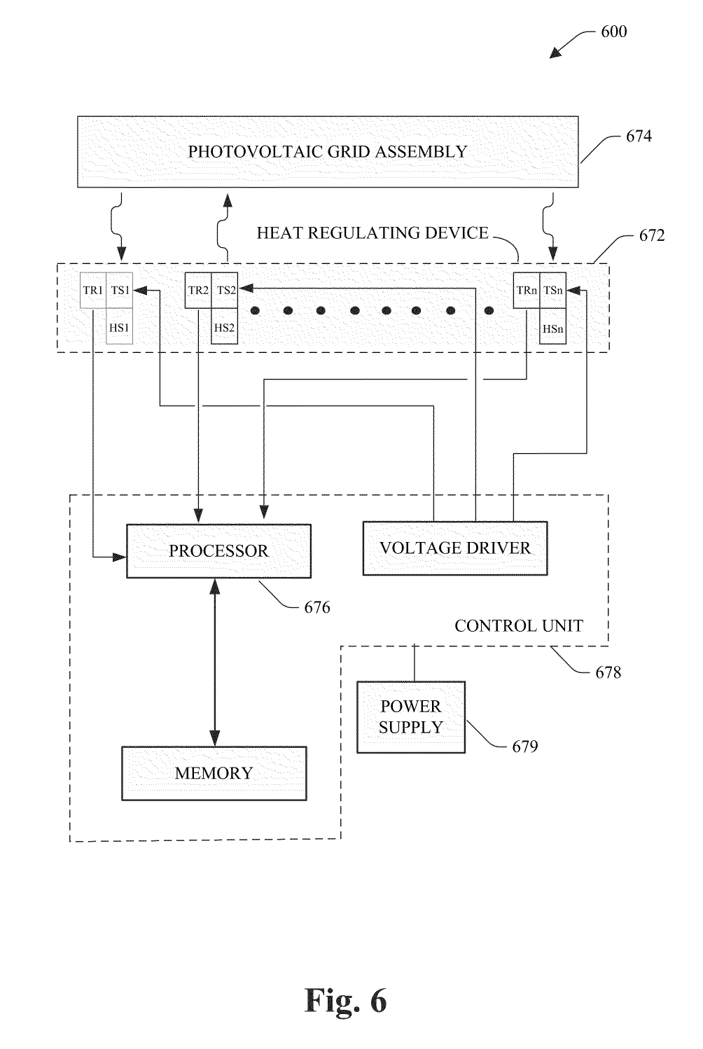

The photovoltaic grid assembly 361 can be divided into an exemplary grid pattern as that shown in FIG. 4. Each grid block (XY) of the grid pattern corresponds to a particular portion of the PV grid assembly 361, and each portion can be individually monitored and controlled for temperature via the control system described below with reference to FIG. 6. In one exemplary aspect, there is one thermo-electrical structure for each temperature measured, allowing the temperatures of the various regions to be controlled individually. In FIG. 4, the temperature amplitudes of each PV cell or segment of the grid portion (X₁Y₁ . . . X₁₂, Y₁₂) are shown with each respective portion of the being monitored for temperature using a respective thermo-electrical structure. Typically, the temperature of the PV grid at a coordinate (e.g. X₃Y₉) that lies beneath a PV cell having a low dissipation rate and an unacceptable temperature (Tu), which is substantially higher than the temperature of the other portions XY of the PV grid. Similarly, during the operation of the PV grid, the temperature of a region of the PV arrangement can reach an unacceptable limit (Tu). The activation of a respective thermo-electrical structure for that region can lower the temperature to the acceptable value (Ta). Accordingly, in one aspect according to the subject innovation, several thermo-electrical structures can manage heat flow from such a region to reach an acceptable temperature for the region.

FIG. 5 illustrates a representative table of temperature amplitudes taken at the various grid blocks, which have been correlated with acceptable temperature amplitude values for the portions of the PV grid assembly mapped by the respective grid blocks. Such data can then be employed by the processors of FIG. 3 & FIG. 6 to determine the grid blocks with undesired temperature outside the acceptable range (Ta range). Subsequently, the undesired temperatures can be brought to an acceptable level via activation of the respective cooling mechanism such as the heat sinks and/or thermo-electrical structure(s).

According to a further aspect, during a typical operation of the photovoltaic grid assembly the location of the hot spots are anticipated, or determined via temperature monitoring, and the corresponding thermo-electrical structure that matches the hot spots can be activated as to take away the heat from the hot spot regions and/or induce heat to other regions of the photovoltaic grid assembly to create a uniform temperature gradient (e.g., mitigate environmental factors such as ice build up). FIG. 6 illustrates a schematic diagram illustrating such a system for controlling the temperature of the photovoltaic grid assembly according to this particular aspect. The system 600 includes a plurality of thermo-electrical structures (TS1, TS2 . . . TS[N]), wherein “N” is an integer. In one aspect, the thermo-electric structures TS are preferably distributed along the back surface of the PV grid assembly 674, and corresponding to respective photo cells device. Each thermo-electrical structure can provide a heat path to a predetermined portion of the PV grid assembly 674 respectively. A plurality of heat sinks (HS1, HS2, . . . HS[N]) are provided, wherein each heat sink HS is operatively coupled to a corresponding thermo-electrical structure TS, respectively, to draw heat away from the PV grid assembly 674. The system 600 also includes a plurality of thermistors (TR1, TR2, . . . TR[N]). Each thermo-electrical structure TS can have a corresponding thermistor TR for monitoring temperature of the respective portion of the PV grid assembly 674 being temperature regulated by the corresponding thermo-electrical structure. In one aspect of the subject innovation, the thermistor TR may be integrated with the thermo-electrical structure TS. Each thermistor TR can be operatively coupled to the processor 676 to provide it with temperature data associated with the respective monitored region of the PV cell modular arrangement. Based on the information received from the thermistors as well as other information (e.g., anticipated location of the hot spots, properties of the PV cells), the processor 676 drives the voltage driver 679 operatively coupled thereto to control the thermo-electrical structure in a desired manner to regulate the temperature of the PV grid 674. The voltage driver can further be charged by the electrical energy generated by the PV grid assembly.

The processor 676 can be part of a control unit 678 that has the ability to sense or display information, or convert analog information into digital, or perform mathematical manipulation of digital data, or interpret the result of mathematical manipulation, or make decisions based on the information. As such, the control unit 678 can be logic unit, a computer or any other intelligent device capable of making decisions based on the data gathered by the thermo-electrical structure and the information provided to it by the heat regulating device. The control unit 678 designates which thermo-electrical structures should be taking away heat from the hot spots, and/or which thermo-electrical structure should induce heat into the PV grid arrangement and/or which one of the thermo-electrical structures should remain inactive. The heat regulating device 672 provides the control unit with data gathered continuously by the thermo-electrical structures about various physical properties of the different regions of the modular arrangements of PV, such as, temperature, power dissipation and the like. In addition, a suitable power supply 679 can also provide operating power to the control unit 678.

Based on the data provided, the control unit 678 makes a decision about the operation of the various portions of the thermo-electrical structure assembly, e.g. deciding what number of the thermo-electrical structures should dissipate heat away and from which hot spots. Accordingly, the control unit 678 can control the heat regulating device 672, which in turn adjusts the heat flow away from and/or into the PV grid 674.

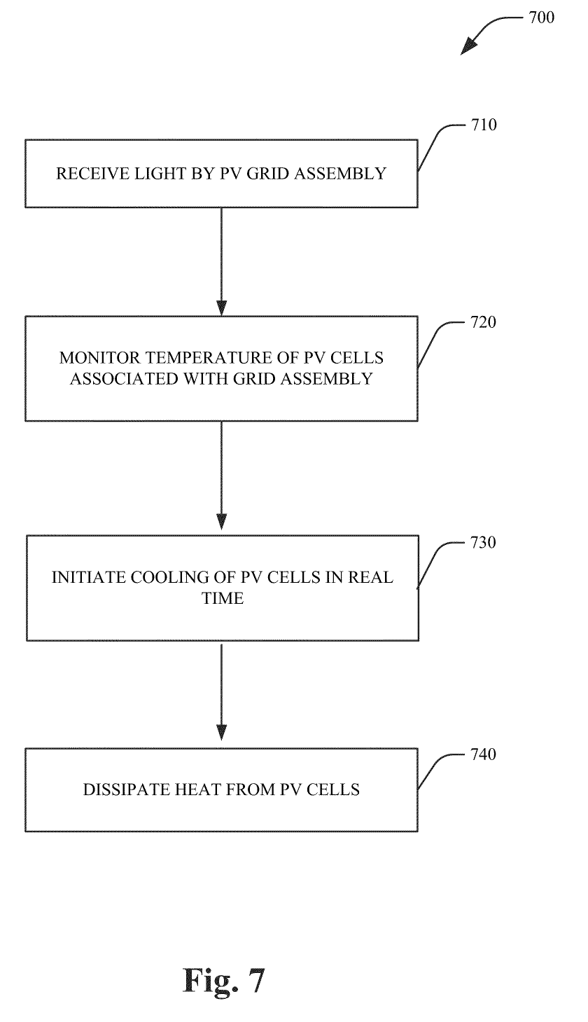

FIG. 7 illustrates a related methodology 700 of dissipating heat from PV cells according to an aspect of the subject innovation. While the exemplary method is illustrated and described herein as a series of blocks representative of various events and/or acts, the subject innovation is not limited by the illustrated ordering of such blocks. For instance, some acts or events may occur in different orders and/or concurrently with other acts or events, apart from the ordering illustrated herein, in accordance with the innovation. In addition, not all illustrated blocks, events or acts, may be required to implement a methodology in accordance with the subject innovation. Moreover, it will be appreciated that the exemplary method and other methods according to the innovation may be implemented in association with the method illustrated and described herein, as well as in association with other systems and apparatus not illustrated or described. Initially, and at 710 incident light can be received by a modular arrangement for grid assembly of PV cells. At 720, temperature of PV cells can be monitored (e.g., via a plurality of temperature sensors associated therewith.). Based in such temperature, at 730 cooling of the PV cells can occur in real time, wherein dissipation of heat occurs from the PV cells at 740, to ensure proper operation.

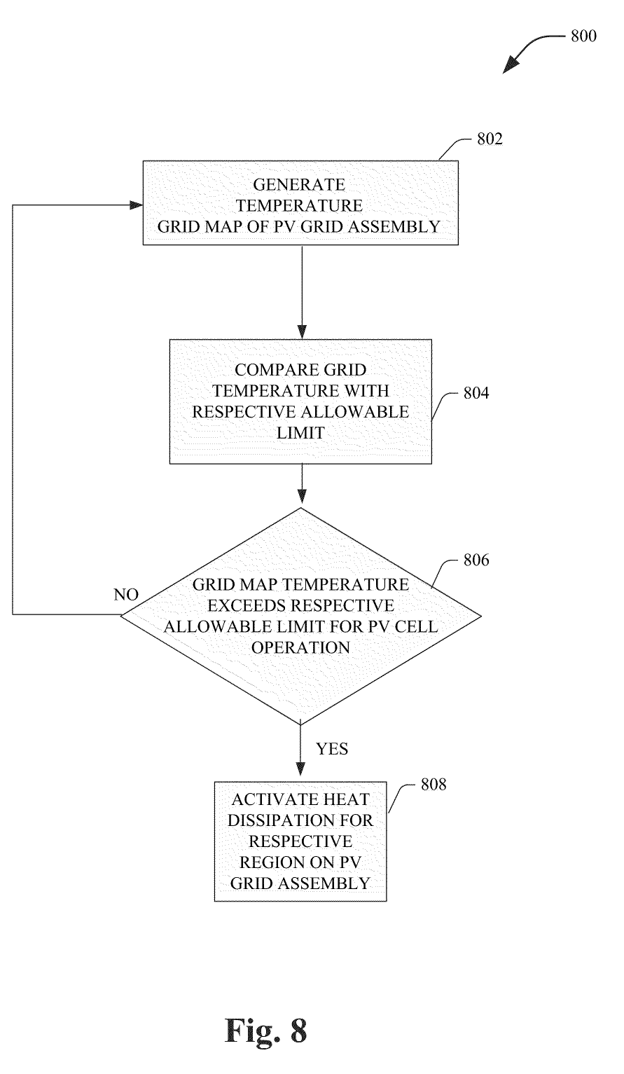

FIG. 8 illustrates a further methodology 800 of heat dissipation for a PV grid assembly according to an aspect of the subject innovation. At 802, the logic unit including the processor generates the temperature grid map for the PV grid assembly. Next, and at 804, temperature for each region is compared to a respective allowable temperature for that region, which ensures efficient operation of the PV cells. Subsequently and at 806, a determination is made, whether the temperature for the region exceed the respective allowable temperature. If so, at 808 the region's respective thermo-electrical structure are activated in conjunction with the heat sinks, to dissipate the heat for that region on the PV grid assembly. Otherwise, the methodology 800 proceeds to act 802 to generate a further temperature grid map of the PV grid assembly, for a cooling thereof.

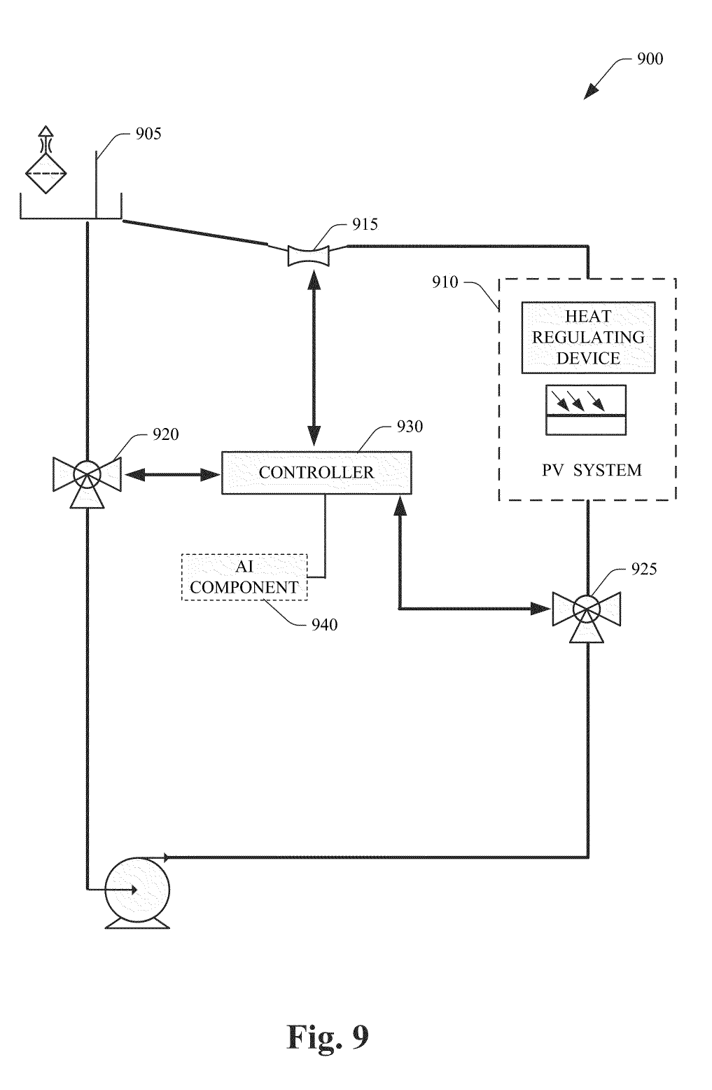

FIG. 9 illustrates a system 900 according to a further aspect of the subject innovation, with a fluid (e.g., water) as the cooling medium being employed to dissipate heat from the fins of the heat sinks and/or and photovoltaic cells of the PV system 910. The system 900 regulates fluid discharge from reservoir 905 (e.g., as part of a pressurized closed loop), wherein check/control valves 920, 925 can regulate liquid flow in a single direction and/or to prevent the flow directly from the reservoir into the heat regulating device of the PV system 910. The system 900 can mitigate thermal stress and material deterioration to prolong system lifetime, and provide for a cooled or heated liquid for other commercial uses. Various sensors associated with a Venturi tube/valve 915 can provide data to the controller 930. For example, sensor analog output signal can be interfaced to a process control microprocessor, programmable controller, or Proportional-Integral-Derivative (PfD) 3-mode controller, wherein output controls the check/control valves 920, 925 to regulate liquid flow as a function of PV cell temperature.

According to a further example, valves 920, 925 can provide a pulsed delivery of the cooling medium. Such pulsing delivery of cooling medium can supply a simple manner for controlling rate of cooling medium application. Moreover, duty cycles can be obtained by controlling the valve for a short duration of time at a set frequency (e.g., 1 to 50 milliseconds with a pulsing frequency of 1 to 50 Hz).

In a related aspect, the system 900 can employ various sensors to assess a health thereof, to diagnose problems for substantially rapid maintenance. For example and as explained earlier, when the cooling medium exits photovoltaic cells it enters a Venturi tube where two pressure sensors permit a measurement of the flow rate of the coolant. Additionally, pressure sensors can further permit verification for existence of adequate coolant is in the system 900, wherein upstream or down stream blockage can be sensed. Moreover, differential temperature computations can further verify heat transfer values for a comparison thereof with predetermined thresholds, for example.

In a related aspect, an AI component 940 can be associated with the controller 930 (or the processors described earlier), to facilitate heat dissipation from the PV cells (e.g., in connection with choosing region(s) dissipating heat, estimating amount of coolant required, manner of valve operation, and the like). For example, a process for determining which region to be selected can be facilitated via an automatic classification system and process. Such classification can employ a probabilistic and/or statistical-based analysis (e.g., factoring into the analysis utilities and costs) to prognose or infer an action that is desired to be automatically performed. For example, a support vector machine (SVM) classifier can be employed. A classifier is a function that maps an input attribute vector, x=(x1, x2, x3, x4, xn), to a confidence that the input belongs to a class—that is, f(x)=confidence(class). Other classification approaches include Bayesian networks, decision trees, and probabilistic classification models providing different patterns of independence can be employed. Classification as used herein also is inclusive of statistical regression that is utilized to develop models of priority.

As used herein, the term “inference” refers generally to the process of reasoning about or inferring states of the system, environment, and/or user from a set of observations as captured via events and/or data. Inference can be employed to identify a specific context or action, or can generate a probability distribution over states, for example. The inference can be probabilistic—that is, the computation of a probability distribution over states of interest based on a consideration of data and events. Inference can also refer to techniques employed for composing higher-level events from a set of events and/or data. Such inference results in the construction of new events or actions from a set of observed events and/or stored event data, whether or not the events are correlated in close temporal proximity, and whether the events and data come from one or several event and data sources. As will be readily appreciated from the subject specification, the subject invention can employ classifiers that are explicitly trained (e.g., via a generic training data) as well as implicitly trained (e.g., via observing system behavior, receiving extrinsic information) so that the classifier(s) is used to automatically determine according to a predetermined criteria which regions to choose. For example, with respect to SVM's which are well understood—it is to be appreciated that other classifier models may also be utilized such as Naive Bayes, Bayes Net, decision tree and other learning models—SVM's are configured via a learning or training phase within a classifier constructor and feature selection module.

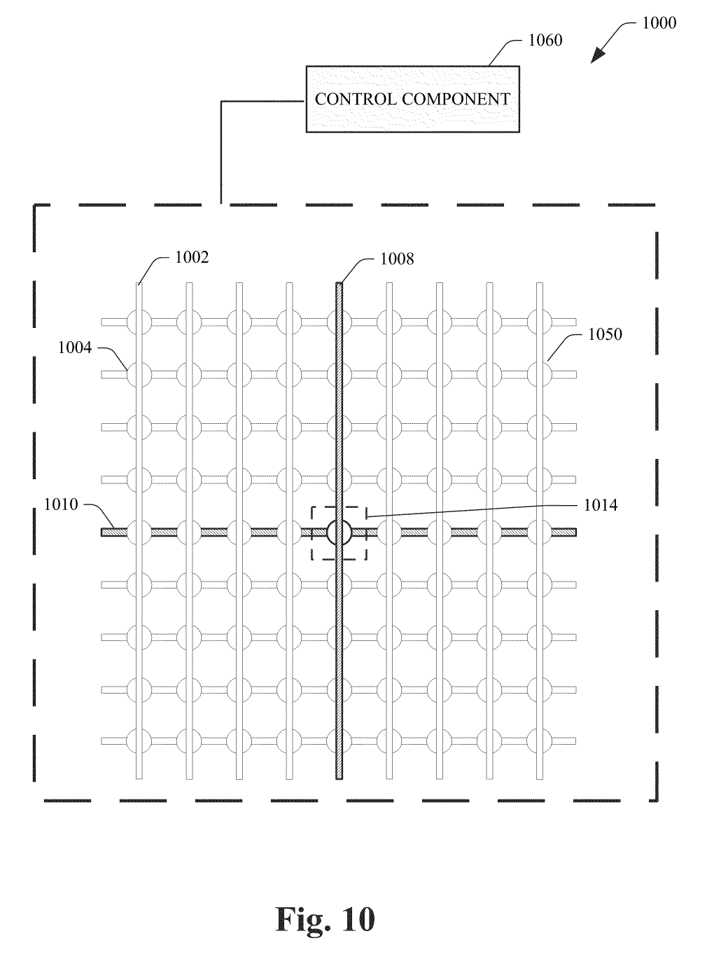

FIG. 10 illustrates a system plan view 1000 for a plurality of solar concentrators that employ a heat regulating assembly according to an aspect of the subject innovation. Such an arrangement can typically include a hybrid system that produces both electrical energy and thermal energy, to facilitate and optimize the energy output in conjunction with energy management. The heat regulating assembly can include a network of conduits (e.g., pipe lines) in grid form of columns 1002, 1008 and rows 1004, 1010—which can further include associated valves/pumps for channeling the cooling medium throughout the arrangement of solar concentrators. The system 1000 can further encompass a combination of concentrator dishes (which can collect light in a focal point—or substantially small focal line), and concentrator troughs (which can collect light to a substantially long focal line.) For example, troughs tend to require simple design and therefore can be well suited for thermal generation. As explained earlier, the thermal energy from dishes that are collected in the process of cooling cells can further serve as pre-heated fluids, which can be subsequently superheated in a dedicated trough or concentrator situated at an end of a coolant loop, for example. The trough or concentrator can superheat fluids to desired temperature level. The system 1000 can further include monitors of output temperatures (not shown) and control of a network of valves via the control component 1060 (e.g., supervisor system), which can be employed to achieve desired temperature. Accordingly, by regulating flow of the cooling medium within the columns 1002, 1008 and rows 1004, 1010—the energy output for both of electrical and thermal energy from corresponding solar concentrators can be optimized.

In one aspect, the control component 1060 can also actively manage (e.g., in real time) tradeoff between thermal energy and PV efficiency, wherein a control network of valves can regulate flow of coolant medium through a solar concentrator. For example, coolant that flows through one PV receiver's heat sink can be routed into two thermal receivers and by splitting the coolant line downstream from the PV receiver, the flow of coolant is halved, hence allowing the coolant to be heated up to a higher temperature as it passes more slowly through the downstream thermal dish. The control component can take as input data such as: current electricity prices that vary based on market conditions (time of year, time of day, weather conditions, and the like); requirement for thermal energy for a particular application; specific current temperature differences between the ambient temperature and the fluid's temperature), and the like. Based on such exemplary inputs, the control component can proactively adjust the coolant pump speeds and opens and/or closes valves to redirect the routing of coolants throughout the thermal loop between dishes and/or troughs—to optimize and create balance between electrical output and thermal output based on predetermined criteria, such as current electricity prices that vary based on market conditions time of year, time of day, weather conditions, requirement for thermal energy for a particular application; specific current temperature differences between the ambient temperature and the fluid's temperature), and the like.

Moreover, the system 1000 can readily detect ruptures (e.g., through a network of pressure sensors, flow rate sensors) distributed throughout the network of valves and columns/rows of conduits). For example, pressure and temperature at different parts of the system can be continuously monitored to detect any changes that can indicate a rupture and/or blockage that signifies a malfunction, e.g., at concentrator 1014, wherein such component can be effectively isolated from the system (e.g., a bypass valve selectively establishes a bypass path for the cooling fluid). It is to be appreciated that controlling and monitoring of the system 1000 can be performed on a dish-by-dish basis, or on any predetermined number of dishes that from a zone or segment of the system 1000. Such decision can be based on costs, response times, efficiency, location, and the like associated with each dish or a group thereof. It is further to be appreciated that even though the methodologies described herein for cooling a dish are primarily described as part of a group of dishes, such methodologies are also applicable for a single dish and can be applied individually as suited.

In a related aspect, each of the solar concentrators can be in form of a modular arrangement that includes various valve(s), sensor(s) and pipe segment(s) integrated as part thereof, to form a module. Such modules can be readily attached/detached to the network of conduits 1002, 1008, 1004, 1010. For example, the solar concentrator 1050 can include a pipe segment with a valve and/or sensors attached thereto, hence forming an integrated module—wherein the sensors can include temperature sensors for measuring: temperature of the cooling medium, temperature of the surrounding environment, pressure, flow rate, and the like. Upon attaching such integrated module to the conduit network, and adjusting the associated valves, the cooling medium can subsequently flow to the solar concentrator 1050 for a cooling thereof. In addition, such integrated solar concentrator module can include a housing that partially or fully contains the solar concentrator, pipe segment(s), valves, sensor and other peripherals/devices associated therewith. Additionally, a Venturi tube can be directly molded in such housing to facilitate measurement procedures.

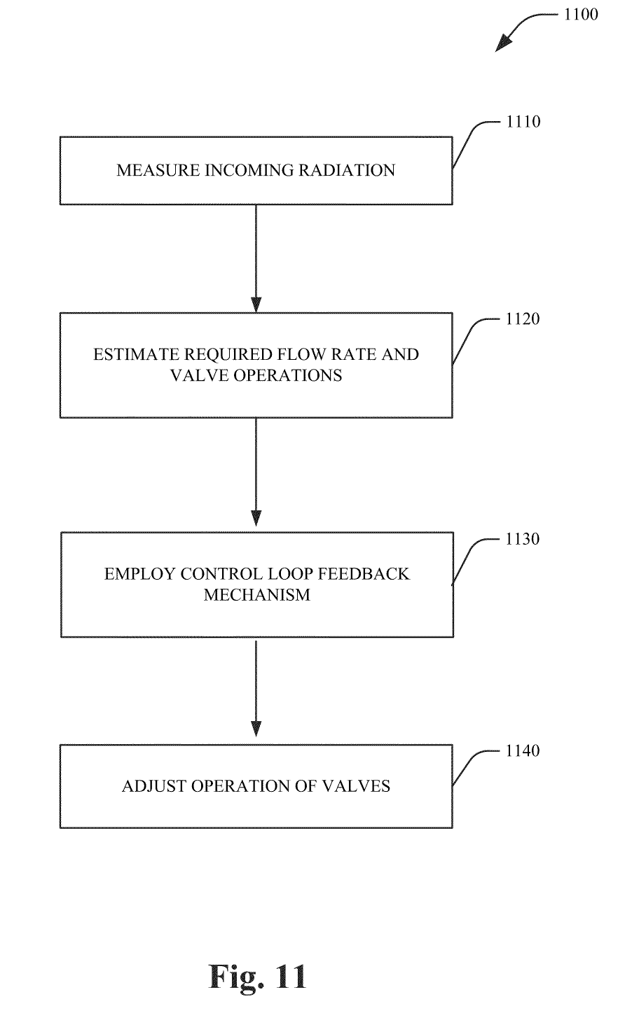

FIG. 11 illustrates a related methodology for operation of the heat regulating assembly according to an aspect of the subject innovation. Initially, and at 1110 an incoming radiation to the system can be measured (e.g., via radiation sensors), and based thereupon a required flow rate for solar concentrators and/or PV cells can be estimated and/or inferred for operations of valves at 1120 (e.g., extent that each valve should be opened and/or closed and flow rate required at each segment of the system.) Subsequently and at 1130, based on collected data (e.g., temperature, pressure, flow rate) a control feedback mechanism is employed to adjust operation of valves at 1140. For example, such closed loop component can further employ a proportional-integral-derivative controller (PID controller) that attempts to correct error between a measured process variable and a desired set point by calculating and then outputting a corrective action that can adjust the process accordingly.

The word “exemplary” is used herein to mean serving as an example, instance or illustration. Any aspect or design described herein as “exemplary” is not necessarily to be construed as preferred or advantageous over other aspects or designs. Similarly, examples are provided herein solely for purposes of clarity and understanding and are not meant to limit the subject innovation or portion thereof in any manner. It is to be appreciated that a myriad of additional or alternate examples could have been presented, but have been omitted for purposes of brevity.

In order to provide a context for the various controllers, control units, and monitors of the disclosed subject matter, FIG. 10 as well as the following discussion are intended to provide a brief, general description of a suitable environment in which the various aspects of the disclosed subject matter may be implemented.

The illustrated aspects may also be practiced in distributed computing environments where tasks are performed by remote processing devices that are linked through a communications network. However, some, if not all aspects of the innovation can be practiced on stand-alone computers. In a distributed computing environment, program modules may be located in both local and remote memory storage devices.

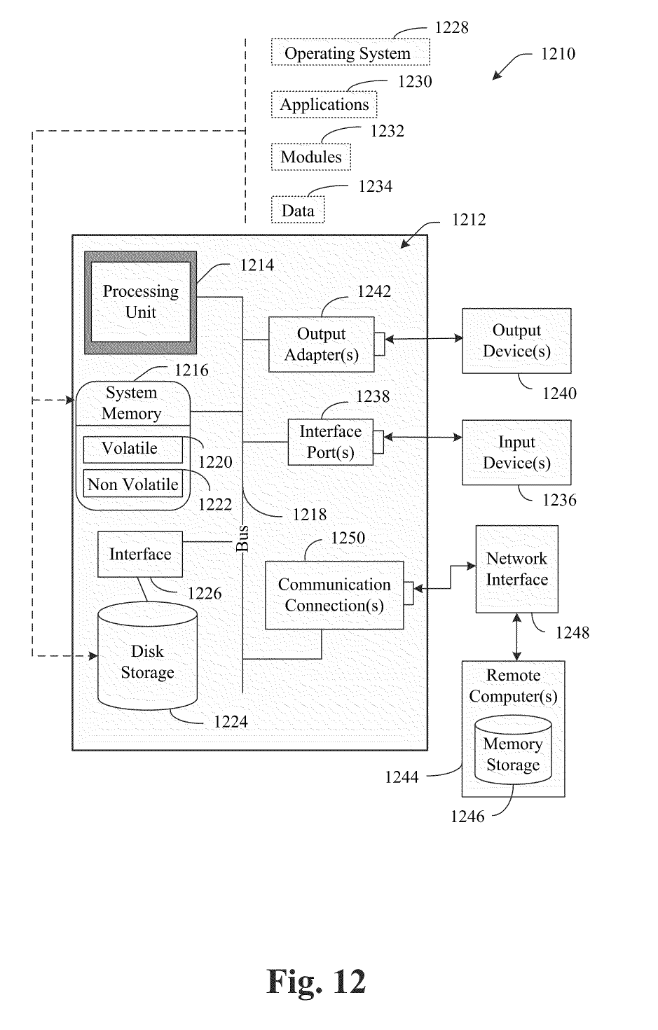

With reference to FIG. 12, an exemplary environment 1210 for implementing various aspects of the controllers or other intelligent devices for the subject innovation is described that includes a computer 1212. The computer 1212 includes a processing unit 1214, a system memory 1216, and a system bus 1218. The system bus 1218 couples system components including, but not limited to, the system memory 1216 to the processing unit 1214. The processing unit 1214 can be any of various available processors. Dual microprocessors and other multiprocessor architectures also can be employed as the processing unit 1214.

The system bus 1218 can be any of several types of bus structure(s) including the memory bus or memory controller, a peripheral bus or external bus, and/or a local bus using any variety of available bus architectures including, but not limited to, 11-bit bus, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Universal Serial Bus (USB), Advanced Graphics Port (AGP), Personal Computer Memory Card International Association bus (PCMCIA), and Small Computer Systems Interface (SCSI).

The system memory 1216 includes volatile memory 1220 and nonvolatile memory 1222. The basic input/output system (BIOS), containing the basic routines to transfer information between elements within the computer 1212, such as during start-up, is stored in nonvolatile memory 1222. By way of illustration, and not limitation, nonvolatile memory 1222 can include read only memory (ROM), programmable ROM (PROM), electrically programmable ROM (EPROM), electrically erasable ROM (EEPROM), or flash memory. Volatile memory 1220 includes random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM).

Computer 1212 also includes removable/non-removable, volatile/nonvolatile computer storage media. FIG. 12 illustrates a disk storage 1224, wherein such disk storage 1224 includes, but is not limited to, devices like a magnetic disk drive, floppy disk drive, tape drive, Jaz drive, Zip drive, LS-60 drive, flash memory card, or memory stick. In addition, disk storage 1224 can include storage media separately or in combination with other storage media including, but not limited to, an optical disk drive such as a compact disk ROM device (CD-ROM), CD recordable drive (CD-R Drive), CD rewritable drive (CD-RW Drive) or a digital versatile disk ROM drive (DVD-ROM). To facilitate connection of the disk storage devices 1224 to the system bus 1218, a removable or non-removable interface is typically used such as interface 1226.

It is to be appreciated that FIG. 12 describes software that acts as an intermediary between users and the basic computer resources described in suitable operating environment 1210. Such software includes an operating system 1228. Operating system 1228, which can be stored on disk storage 1224, acts to control and allocate resources of the computer system 1212. System applications 1230 take advantage of the management of resources by operating system 1228 through program modules 1232 and program data 1234 stored either in system memory 1216 or on disk storage 1224. It is to be appreciated that various components described herein can be implemented with various operating systems or combinations of operating systems.

A user enters commands or information into the computer 1212 through input device(s) 1236. Input devices 1236 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 1214 through the system bus 1218 via interface port(s) 1238. Interface port(s) 1238 include, for example, a serial port, a parallel port, a game port, and a universal serial bus (USB). Output device(s) 1240 use some of the same type of ports as input device(s) 1236. Thus, for example, a USB port may be used to provide input to computer 1212, and to output information from computer 1212 to an output device 1240. Output adapter 1242 is provided to illustrate that there are some output devices 1240 like monitors, speakers, and printers, among other output devices 1240 that require special adapters. The output adapters 1242 include, by way of illustration and not limitation, video and sound cards that provide a means of connection between the output device 1240 and the system bus 1218. It should be noted that other devices and/or systems of devices provide both input and output capabilities such as remote computer(s) 1244.

Computer 1212 can operate in a networked environment using logical connections to one or more remote computers, such as remote computer(s) 1244. The remote computer(s) 1244 can be a personal computer, a server, a router, a network PC, a workstation, a microprocessor based appliance, a peer device or other common network node and the like, and typically includes many or all of the elements described relative to computer 1212. For purposes of brevity, only a memory storage device 1246 is illustrated with remote computer(s) 1244. Remote computer(s) 1244 is logically connected to computer 1212 through a network interface 1248 and then physically connected via communication connection 1250. Network interface 1248 encompasses communication networks such as local-area networks (LAN) and wide-area networks (WAN). LAN technologies include Fiber Distributed Data Interface (FDDI), Copper Distributed Data Interface (CDDI), Ethernet/IEEE 802.3, Token Ring/IEEE 802.5 and the like. WAN technologies include, but are not limited to, point-to-point links, circuit switching networks like Integrated Services Digital Networks (ISDN) and variations thereon, packet switching networks, and Digital Subscriber Lines (DSL).

Communication connection(s) 1250 refers to the hardware/software employed to connect the network interface 1248 to the bus 1218. While communication connection 1250 is shown for illustrative clarity inside computer 1212, it can also be external to computer 1212. The hardware/software necessary for connection to the network interface 1248 includes, for exemplary purposes only, internal and external technologies such as, modems including regular telephone grade modems, cable modems and DSL modems, ISDN adapters, and Ethernet cards.

What has been described above includes various exemplary aspects. It is, of course, not possible to describe every conceivable combination of components or methodologies for purposes of describing these aspects, but one of ordinary skill in the art may recognize that many further combinations and permutations are possible. Accordingly, the aspects described herein are intended to embrace all such alterations, modifications and variations that fall within the spirit and scope of the appended claims.

Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A system for solar energy concentration comprising:
a plurality of solar concentrators;
a heat regulating assembly having conduits that conveys a cooling medium for dissipation of heat generated from the solar concentrators, flow of the cooling medium controlled by a plurality of valves; and
a control component that controls operation of the valves in real time based on data collected from the system and temperature of the solar concentrators.

2. The system of claim 1, a solar concentrator as part of the plurality of solar concentrators is a solar thermal.

3. The system of claim 1, a further solar concentrator as part of the plurality of solar connectors includes a modular arrangement of photovoltaic (PV) cells.

4. The system of claim 1, the data includes at least one of a temperature, pressure, or flow rate of the cooling medium.

5. The system of claim 3, the data is the temperature of the photovoltaic cells.

6. The system of claim 3 further comprising a pump(s) that facilitates flow of the cooling medium throughout the conduits.

7. The system of claim 1, the conduit is a pipeline.

8. The system of claim 1, the cooling medium free flows through the conduit.

9. The system of claim 1, flow of the cooling medium is pressurized.

10. The system of claim 1 further comprising an artificial intelligence component that facilitates heat dissipation from the plurality of solar concentrators.

11. A method of regulating heat flow comprising:
receiving radiation by a solar concentrator(s);
estimating by a heat regulation device amount of cooling medium required to dissipate heat generated by the solar concentrator(s); and
regulating operation of valves to facilitate flow of the cooling medium based on temperature measured from the solar concentrator(s).

12. The method of claim 11, the regulating act based on measurements of flow within a Venturi tube.

13. The method of claim 11 further comprising monitoring temperature of PV cells associated with the solar concentrators.

14. The method of claim 13 further comprising regulating in real-time heat dissipation from the PV cells based on the monitoring act.

15. The method of claim 11 further comprising supplying the cooling medium as a pre-heated fluid to customers or for subsequent heating thereof.

16. The method of claim 13 further comprising generating temperature grid map of an assembly for the PV cells.

17. The method of claim 11, the regulating act based on data collected from the cooling medium.

18. The method of claim 11 further comprising employing a closed loop control to mitigate errors.

19. The method of claim 11 further comprising detecting faults in circulation of the cooling medium via at least one of a change in pressure, flow rate, or velocity of the cooling medium.

20. A heat regulating assembly comprising:
means for cooling solar concentrator in real time via flow of a medium through valves; and
means for regulating operation of the valves.

21. A method of optimizing energy output from a plurality of solar concentrators, comprising:
generating energy from both solar thermals and PV cells;
absorbing heat from the solar thermals and PV cells via a cooling medium;
varying the absorbing act based on regulating valves that control flow of the cooling medium based on temperatures measured from the solar thermals or the PV cells, or a combination thereof, and
optimizing the generating act based on predetermined criteria.

22. The method of claim 21, the predetermined criteria includes one of electricity prices or temperature difference between an ambient temperature and temperature of the cooling medium.

23. An integrated solar concentrator module comprising;
a solar concentrator
a pipe segment with a valve; and
the pipe segment connected to the solar concentrator for a cooling thereof via a cooling medium regulated by the valve, the pipe segment attachable to a pipe line that transports the cooling medium.

24. The integrated solar concentrator module of claim 23 further comprising a sensor(s) that measures pressure, velocity, temperature, or flow rate of the cooling medium.

25. The integrated solar concentrator module of claim 23 further comprising a housing that one of partially or fully contains the integrated solar concentrator.

26. The integrated solar concentrator module of claim 25 further comprising a Venturi directly molded into the housing.
